(19) United States
(12) Patent Application Publication
(10) Pub. No.: US 2025/0391480 A1
(43) Pub. Date: Dec. 25, 2025

(54) SIGNAL RECEIVING CIRCUIT, MEMORY STORAGE DEVICE AND REFERENCE VOLTAGE ADJUSTMENT METHOD

(71) Applicant: PHISON ELECTRONICS CORP., Miaoli (TW)

(72) Inventors: Kun-Ruei Li, Taichung City (TW); Yu-Chiang Liao, Miaoli County (TW)

(73) Assignee: PHISON ELECTRONICS CORP., Miaoli (TW)

(21) Appl. No.: 18/774,928

(22) Filed: Jul. 17, 2024

(30) Foreign Application Priority Data
Jun. 20, 2024 (TW) 113122911

(51) Int. Cl. G11C 16/28; G11C 16/34

(52) U.S. Cl. CPC G11C 16/28; G11C 16/3404

(57) ABSTRACT

A signal receiving circuit, a memory storage device, and a reference voltage adjustment method are provided. The method includes: obtaining a first signal and a plurality of reference voltage levels; sensing a voltage relative relationship between the first signal and the plurality of reference voltage levels, where the voltage relative relationship reflects bit data carried by the first signal; detecting edge information of the first signal; and adjusting at least one of the plurality of reference voltage levels according to the edge information.

### CROSS-REFERENCE TO RELATED APPLICATION

This application claims the priority benefit of Taiwan application serial no. 113122911, filed on Jun. 20, 2024. The entirety of the above-mentioned patent application is hereby incorporated by reference herein and made a part of this specification.

### BACKGROUND

### Technical Field

The disclosure relates to a signal receiving circuit, a memory storage device, and a reference voltage adjustment method.

### Description of Related Art

With the development of data transmission technology, to increase data transmission bandwidth, some types of memory storage devices support pulse amplitude modulation (PAM) technology of signals, so as to increase the number of bits transmitted per time unit (equivalent to increasing the bit depth of the bit data carried by the transmitted signal). However, for the signal receiving end (e.g., a memory storage device), the memory storage device must use more and more accurate reference voltage levels to sense (e.g., sample) the signal in order to correctly identify the bit data actually carried by the signal.

In some cases, once the operating environment (e.g., temperature) of the memory storage device changes or the signal is interfered during transmission, causing the eye diagram of the signal to change, the memory storage device uses a predetermined reference voltage level to sense the signal, which can easily lead to a large number of errors. Generally, if a large number of errors are detected in a short period of time, the memory storage device will reestablish the connection between the memory storage device and the host system, including re-performing a handshake operation with the host system, so as to ensure that the subsequently received signals may be correctly identified. However, the above operation must wait until a large number of errors occur before performing the connection reestablishment, which makes the memory storage device inefficient in error handling. Further, if the memory storage device repeatedly performs connection reestablishment in a short period of time due to temporary factors such as changes in the operating environment, the host system may determine easily and accordingly that the signal transmission stability of the memory storage device is poor.

### SUMMARY

The disclosure provides a signal receiving circuit, a memory storage device, and a reference voltage adjustment method capable of improving the above problems.

An exemplary embodiment of the disclosure provides a signal receiving circuit including a multi-stage sensing circuit, an edge detecting circuit, and a control circuit. The control circuit is coupled to the multi-stage sensing circuit and the edge detecting circuit. The multi-stage sensing circuit is configured to obtain a first signal and a plurality of reference voltage levels. The multi-stage sensing circuit is further configured to sense a voltage relative relationship between the first signal and the plurality of reference voltage levels. The voltage relative relationship reflects bit data carried by the first signal. The edge detecting circuit is configured to detect edge information of the first signal. The control circuit is configured to adjust at least one of the plurality of reference voltage levels according to the edge information.

An exemplary embodiment of the disclosure further provides a memory storage device including a connection interface unit, a rewritable non-volatile memory module, and a memory control circuit unit. The connection interface unit is configured to be coupled to a host system. The memory control circuit unit is coupled to the connection interface unit and the rewritable non-volatile memory module. The connection interface unit includes a signal receiving circuit. The signal receiving circuit is configured to: obtain a first signal and a plurality of reference voltage levels, sense a voltage relative relationship between the first signal and the plurality of reference voltage levels, where the voltage relative relationship is configured to identify bit data carried by the first signal, detect edge information of the first signal, and adjust at least one of the plurality of reference voltage levels according to the edge information.

An exemplary embodiment of the disclosure further provides a reference voltage adjustment method for a memory storage device. The reference voltage adjustment method includes the following steps. A first signal and a plurality of reference voltage levels are obtained. A voltage relative relationship between the first signal and the plurality of reference voltage levels are sensed, where the voltage relative relationship is configured to identify bit data carried by the first signal. Edge information of the first signal is detected. At least one of the plurality of reference voltage levels is adjusted according to the edge information.

To sum up, after the first signal and the plurality of reference voltage levels are obtained, the voltage relative relationship between the first signal and the plurality of reference voltage levels is sensed. In particular, the voltage relative relationship reflects the bit data carried by the first signal. On the other hand, the edge information of the first signal is detected, and the edge information is used to adjust at least one of the plurality of reference voltage levels. In this way, the anti-interference capability (for example, errors in the received signal are reduced) of the signal receiving device is improved without affecting the signal transmission performance of the signal receiving device.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of a signal receiving circuit according to an exemplary embodiment of the disclosure

FIG. 2 is a schematic diagram illustrating a relative voltage relationship between a first signal and a plurality of reference voltage levels according to an exemplary embodiment of the disclosure.

FIG. 3 is a schematic diagram of a sensing circuit according to an exemplary embodiment of the disclosure.

FIG. 4 is a schematic view of adjusting the reference voltage levels according to an exemplary embodiment of the disclosure.

FIG. 5 is a schematic diagram illustrating determination of a first critical voltage and a second critical voltage according to an exemplary embodiment of the disclosure.

FIG. 6 is a schematic diagram of a signal receiving circuit according to an exemplary embodiment of the disclosure

FIG. 7 is a schematic view illustrating a memory storage device according to an exemplary embodiment of the disclosure.

FIG. 8 is a flow chart illustrating a signal generation method according to an exemplary embodiment of the disclosure.

### DESCRIPTION OF THE EMBODIMENTS

Several exemplary embodiments are provided in the following paragraphs to illustrate the disclosure, but the disclosure is not limited to the illustrated exemplary embodiments. Further, appropriate combinations of the exemplary embodiments are also permitted. The term “coupled to” used in the entire specification (including claims) refers to any direct or indirect connecting means. For instance, if the disclosure describes a first device is coupled to a second device, the description should be explained as the first device is connected directly to the second device, or the first device, through connecting other device or using certain connecting means, is connected indirectly to the second device. In addition, the term “signal” may refer to at least one current, voltage, charge, temperature, data, or any other one or more signals.

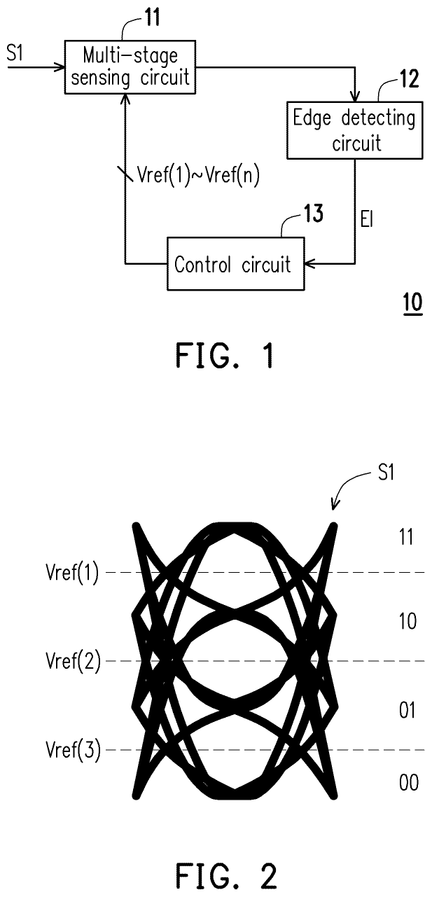

FIG. 1 is a schematic diagram of a signal receiving circuit according to an exemplary embodiment of the disclosure With reference to FIG. 1, a signal receiving circuit 10 includes a sensing circuit (also referred to as a multi-stage sensing circuit) 11, a detecting circuit (also referred to as an edge detecting circuit) 12, and a control circuit 13.

The sensing circuit 11 is configured to obtain (e.g., receive) a signal (also referred to as a first signal) S1 and a plurality of reference voltage levels Vref(1) to Vref(n). In an exemplary embodiment, the signal S1 may be generated at a source end by pulse amplitude modulation (PAM) technology or similar technology. In this way, by adjusting a voltage of the signal S1, the signal S1 may be used to transmit various types of data.

In an exemplary embodiment, the total number of the reference voltage levels Vref(1) to Vref(n) is “3”. In an exemplary embodiment, the total number of the reference voltage levels Vref(1) to Vref(n) may be other numbers greater than “1”, which is not limited by the disclosure.

The sensing circuit 11 is configured to sense a voltage relative relationship between the signal S1 and the reference voltage levels Vref(1) to Vref(n). For instance, this voltage relative relationship may include that the voltage of the signal S1 is higher than or lower than at least one of the reference voltage levels Vref(1) to Vref(n). In an exemplary embodiment, the sensing circuit 11 may compare the voltage of the signal S1 with at least one of the reference voltage levels Vref(1) to Vref(n), so as to obtain the voltage relative relationship between the signal S1 and the reference voltage levels Vref(1) to Vref(n). In particular, this voltage relative relationship may be used to identify bit data carried by the signal S1.

In an exemplary embodiment, the reference voltage levels Vref(1) to Vref(n) include at least reference voltage levels Vref(i) and Vref(j). i is different from j, and both i and j are positive integers between 1 and n. In an exemplary embodiment, the reference voltage level Vref(i) is also referred to as a first reference voltage level, and the reference voltage level Vref(j) is also referred to as a second reference voltage level. The reference voltage level Vref(i) is different from the reference voltage level Vref(j). For the convenience of description, it is assumed in the following paragraphs that the reference voltage level Vref(i) is higher than the reference voltage level Vref(j).

In an exemplary embodiment, if the voltage relative relationship between the signal S1 and the reference voltage levels Vref(i) and Vref(j) is that the voltage of the signal S1 is higher than the reference voltage level Vref(i), then this voltage relative relationship may reflect that the bit data carried by the current signal S1 is a specific type of bit data (also referred to as first bit data). Alternatively, in an exemplary embodiment, if the voltage relative relationship between the signal S1 and the reference voltage levels Vref(i) and Vref(j) is that the voltage of the signal S1 is between the reference voltage levels Vref(i) and Vref(j), then this voltage relative relationship may reflect that the bit data carried by the current signal S1 is another specific type of bit data (also referred to as second bit data). Further, in an exemplary embodiment, if the voltage relative relationship between the signal S1 and the reference voltage levels Vref(i) and Vref(j) is that the voltage of the signal S1 is lower than the reference voltage level Vref(j), then this voltage relative relationship may reflect that the bit data carried by the current signal S1 is still another specific type of bit data (also referred to as third bit data). The first bit data, the second bit data, and the third bit data may be different.

In an exemplary embodiment, a bit depth of the bit data carried by the signal S1 is at least “2”. That is, the voltage relative relationship sensed by the sensing circuit 11 each time may reflect a combination of “2” bits, such as one of “11”, “10”, “01”, and “00”. In an exemplary embodiment, if the bit depth of the bit data carried by the signal S1 is deeper, the voltage relative relationship sensed by the sensing circuit 11 each time may reflect a combination of more bits, which is not limited by the disclosure.

FIG. 2 is a schematic diagram illustrating a voltage relative relationship between a first signal and a plurality of reference voltage levels according to an exemplary embodiment of the disclosure. With reference to FIG. 2, which illustrates the eye diagram of the signal S1. It should be noted that the eye diagram of the signal S1 may be changed according to actual circumstances, which is not limited by the disclosure. In addition, it is assumed that the reference voltage levels Vref(1) to Vref(n) include reference voltage levels Vref(1) to Vref(3). The reference voltage level Vref(1) is higher than the reference voltage level Vref(2), and the reference voltage level Vref(2) is higher than the reference voltage level Vref(3).

In the exemplary embodiment shown in FIG. 2, if the voltage relative relationship between the signal S1 and the reference voltage levels Vref(1) to Vref(3) sensed by the sensing circuit 11 is that the voltage of the signal S1 is higher than the reference voltage level Vref(1), then this voltage relative relationship may reflect that the bit data carried by the current signal S1 is “11”. If the voltage relative relationship between the signal S1 and the reference voltage levels Vref(1) to Vref(3) sensed by the sensing circuit 11 is that the voltage of the signal S1 is between the reference voltage levels Vref(1) and Vref(2), then this voltage relative relationship may reflect that the bit data carried by the current signal S1 is “10”. If the voltage relative relationship between the signal S1 and the reference voltage levels Vref(1) to Vref(3) sensed by the sensing circuit 11 is that the voltage of the signal S1 is between the reference voltage levels Vref(2) and Vref(3), then this voltage relative relationship may reflect that the bit data carried by the current signal S1 is “01”. Alternatively, if the voltage relative relationship between the signal S1 and the reference voltage levels Vref(1) to Vref(3) sensed by the sensing circuit 11 is that the voltage of the signal S1 is lower than the reference voltage level Vref(3), then this voltage relative relationship may reflect that the bit data carried by the current signal S1 is “00”. It should be noted that the bit data corresponding to the relative relationship between each voltage in the exemplary embodiment of FIG. 2 may also be adjusted according to practical needs, which is not limited by the disclosure.

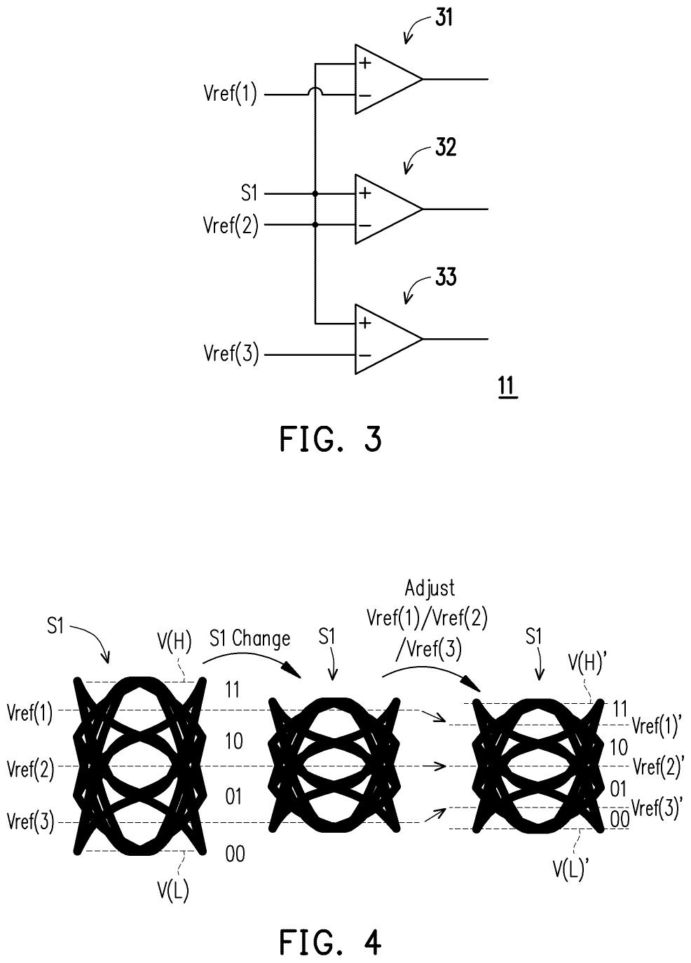

FIG. 3 is a schematic diagram of a sensing circuit according to an exemplary embodiment of the disclosure. With reference to FIG. 3, in an exemplary embodiment, the sensing circuit 11 may include comparison circuits 31 to 33. The comparison circuit 31 may receive the signal S1 and the reference voltage level Vref(1) and generate an output according to a comparison result between the voltage of the signal S1 and the reference voltage level Vref(1). The comparison circuit 32 may receive the signal S1 and the reference voltage level Vref(2) and generate an output according to a comparison result between the voltage of the signal S1 and the reference voltage level Vref(2). The comparison circuit 33 may receive the signal S1 and the reference voltage level Vref(3) and generate an output according to a comparison result between the voltage of the signal S1 and the reference voltage level Vref(3). The sensing circuit 11 may obtain the voltage relative relationship between the signal S1 and the reference voltage levels Vref(1) to Vref(3) according to the outputs of the comparison circuits 31 to 33. For instance, the comparison circuits 31 to 33 may be sense amplifiers (SA) or other types of comparison circuits.

It should be noted that in the exemplary embodiment of FIG. 3, the total number of comparison circuits 31 to 33 is “3”, and each comparison circuit is configured to compare the voltage of the signal S1 with one single reference voltage level. However, in an exemplary embodiment, the total number of comparison circuits 31 to 33 may be more or less, and each comparison circuit may also be configured to compare the voltage of the signal S1 with a plurality of reference voltage levels, depending on the circuit design inside the sensing circuit 11, which is not limited by the disclosure.

It should be noted that if an operating environment (e.g., temperature) of the signal receiving circuit 10 changes or the signal S1 is interfered during transmission, causing the eye diagram of the signal S1 to change, continuously using the predetermined reference voltage levels Vref(1) to Vref(n) to sample (or compare) the signal S1 to obtain the voltage relative relationship may result in a large number of errors in the sensing results. In an exemplary embodiment, by dynamically adjusting at least one of the reference voltage levels Vref(1) to Vref(n) during the operation of the signal receiving circuit 10, this problem may be effectively improved, and that an anti-interference capability (e.g., reducing errors in the received signal S1) of the signal receiving circuit 10 may be improved without affecting the signal transmission performance of the signal receiving circuit 10.

With reference to FIG. 1 again, the detecting circuit 12 is coupled to the sensing circuit 11. The detecting circuit 12 is configured to detect edge information EI of the signal S1. For instance, the detecting circuit 12 may include an eye diagram drawing circuit, an eye height detector, and/or an eye width detector. The eye diagram drawing circuit may be configured to record the voltage of the signal S1 according to the continuously received signal S1 and draw the eye diagram of the signal S1. The eye height detector may be configured to detect an eye height of the signal S1. The eye width detector may be configured to detect an eye width of the signal S1.

In an exemplary embodiment, the edge information EI of the signal S1 may reflect that the voltage of the signal S1 varies (e.g., fluctuates up and down) between a specific critical voltage (also referred to as a first critical voltage) and another critical voltage (also referred to as a second critical voltage). In an exemplary embodiment, the edge information EI of the signal S1 may also reflect that, within a specific time range, the voltage of the signal S1 always remains within a voltage range formed by the first critical voltage and the second critical voltage. For instance, within this time range, the voltage of the signal S1 may move (i.e., change) within this voltage range. For instance, if the first critical voltage is higher than the second critical voltage, the first critical voltage may be an upper limit of the voltage range, and the second critical voltage may be a lower limit of the voltage range.

The control circuit 13 is coupled to the sensing circuit 11 and the detecting circuit 12. The control circuit is configured to adjust at least one of the reference voltage levels Vref(1) to Vref(n) according to the edge information EI of the signal S1. For instance, the control circuit 13 may adjust the reference voltage level Vref(i) to Vref(i)′ according to the edge information EI of the signal S1. The control circuit 13 may use the reference voltage level Vref(i)′ to replace the reference voltage level Vref(i) and provide the reference voltage level Vref(i)′ to the sensing circuit 11 for use by the sensing circuit 11. In an exemplary embodiment, compared to the reference voltage level Vref(i), the sensing circuit 11 uses the reference voltage level Vref(i)′ to compare with the voltage of the signal S1, which can improve the anti-interference capability (for example, errors in the received signal S1 are reduced) of the signal receiving circuit 10.

In an exemplary embodiment, according to the edge information EI of the signal S1, the control circuit 13 may continuously monitor the change of at least one of the first critical voltage and the second critical voltage. The control circuit 13 may adjust at least one of the reference voltage levels Vref(1) to Vref(n) according to this change.

In an exemplary embodiment, it is assumed that the edge information EI of the signal S1 reflects that the first critical voltage changes from a specific voltage (also referred to as a first voltage) to another voltage (also referred to as a second voltage), and/or the second critical voltage changes from a specific voltage (also referred to as a third voltage) to another voltage (also referred to as a fourth voltage). The control circuit 13 may obtain at least one new reference voltage level according to at least one of the second voltage and the fourth voltage. Next, the control circuit 13 may adjust (or replace) at least one of the reference voltage levels Vref(1) to Vref(n) according to the new reference voltage level.

FIG. 4 is a schematic view of adjusting the reference voltage levels according to an exemplary embodiment of the disclosure. With reference to FIG. 4, in an exemplary embodiment, it is assumed that the edge information EI of the signal S1 reflects that the voltage of the signal S1 changes from changing between a voltage V(H) (also referred to as the first critical voltage) and a voltage V(L) (also referred to as the second critical voltage) in a previous time range (also referred to as a first time range) to changing between a new voltage V(H)′ (also referred to as a new first critical voltage) and a new voltage V(L)′ (also referred to as a new second critical voltage) in another time range (also referred to as a second time range). Therefore, in the second time range, if the bit data carried by the signal S1 is continuously identified based on the voltage relative relationship between the signal S1 and the reference voltage levels Vref(1) to Vref(3), there is a high probability that a large number of errors may exist in the identified bit data.

In an exemplary embodiment, in the second time range, the control circuit 13 may determine new reference voltage levels Vref(1) to Vref(3) (i.e., reference voltage levels Vref(1)′ to Vref(3)′) based on the voltage V(H)′ (i.e., the new first critical voltage) and/or the voltage V(L)′ (i.e., the new second critical voltage). The control circuit 13 may adjust the reference voltage levels Vref(1) to Vref(3) to the reference voltage levels Vref(1)′ to Vref(3)′ respectively. According to the reference voltage levels Vref(1)′ to Vref(3)′, within the second time range (i.e., the voltage of signal S1 continues to change between the voltage V(H)′ and V(L)′), the voltage relative relationship between the signal S1 and the reference voltage levels Vref(1)′ to Vref(3)′ may more accurately reflect or be used to identify the bit data carried by the signal S1.

In an exemplary embodiment, the control circuit 13 may determine the reference voltage levels Vref(1)′ to Vref(3)′ according to the following equations (1.1) to (1.3).

$${Vref ( 1 )}^{′} = ( 5 \times {V ( H )}^{′} + {V ( L )}^{′} ) / 6 \qquad ( 1.1 )$$

$${Vref ( 2 )}^{′} = ( {V ( H )}^{′} + {V ( L )}^{′} ) / 2 \qquad ( 1.2 )$$

$${Vref ( 3 )}^{′} = ( {V ( H )}^{′} + 5 \times {V ( L )}^{′} ) / 6 \qquad ( 1.3 )$$

It should be noted that equations (1.1) to (1.3) may also be adjusted according to actual needs, which is not limited by the disclosure. Alternatively, in an exemplary embodiment, the control circuit 13 may also query a data table according to the voltage V(H)′ (i.e., the new first critical voltage) and/or the voltage V(L)′ (i.e., the new second critical voltage) to obtain the reference voltage levels Vref(1)′ to Vref(3)′, which is not limited by the disclosure. Further, in an exemplary embodiment, the remaining reference voltage levels among the reference voltage levels Vref(1) to Vref(n) may also be adjusted in a similar manner, which is not limited by the disclosure.

In an exemplary embodiment, the voltage V(H) (or the voltage V(H)′) may reflect an average value (also referred to as a first average value) of the voltage of the signal S1 within a jitter range (also referred to as a first jitter range) near a voltage upper limit of the signal S1. In an exemplary embodiment, the control circuit 13 may determine the voltage V(H) (or voltage V(H)′) based on this first average value. For instance, the voltage V(H) (or the voltage V(H)′) may be the same as or positively correlated with this first average value.

In an exemplary embodiment, the voltage V(L) (or the voltage V(L)′) may reflect an average value (also referred to as a second average value) of the voltage of the signal S1 within a jitter range (also referred to as a second jitter range) near a voltage lower limit of the signal S1. In an exemplary embodiment, the control circuit 13 may determine the voltage V(L) (or voltage V(L)′) based on this second average value. For instance, the voltage V(L) (or the voltage V(L)′) may be the same as or positively correlated with this second average value.

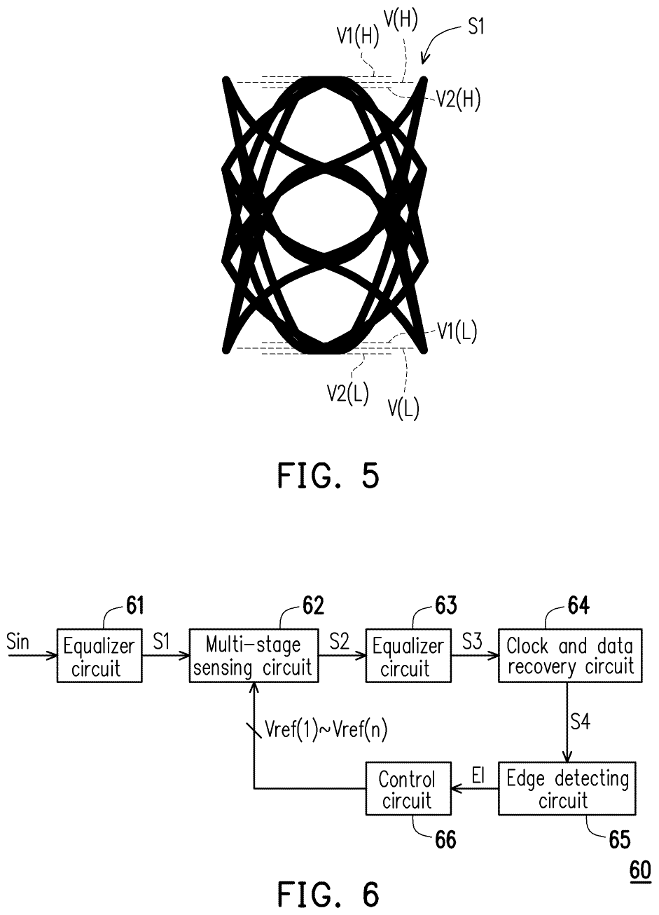

FIG. 5 is a schematic diagram illustrating determination of a first critical voltage and a second critical voltage according to an exemplary embodiment of the disclosure. With reference to FIG. 5, it is assumed that near the voltage upper limit of the signal S1, the voltage of the signal S1 jitters between the voltages V1(H) and V2(H). In this case, the voltage range between the voltages V1(H) and V2(H) may be regarded as the first jitter range. The control circuit 13 may determine the voltage V(H) according to the average value (i.e., the first average value) of the voltages V1(H) and V2(H). For instance, the voltage V(H) may be the same as or positively correlated to the average value of the voltages V1(H) and V2(H). Similarly, after a voltage variation range of the signal S1 changes, the voltage V(H)′ may be determined in a similar manner, so description thereof is not repeated herein.

On the other hand, it is assumed that the voltage of the signal S1 jitters between the voltages V1(L) and V2(L) near the voltage lower limit of the signal S1. In this case, the voltage range between the voltages V1(L) and V2(L) may be regarded as the second jitter range. The control circuit 13 may determine the voltage V(L) according to the average value (i.e., the second average value) of the voltages V1(L) and V2(L). For instance, the voltage V(L) may be the same as or positively correlated to the average value of the voltages V1(L) and V2(L). Similarly, after the voltage variation range of the signal S1 changes, the voltage V(L)′ may be determined in a similar manner, so description thereof is not repeated herein.

In an exemplary embodiment, the control circuit 13 may determine whether the change of at least one of the voltage V(H) (i.e., the first critical voltage) and the voltage V(L) (i.e., the second critical voltage) is greater than a critical value. Taking FIG. 4 as an example, the control circuit 13 may determine whether a difference value (also referred to as a first difference value) between the voltage V(H) and the voltage V(H)′ or a difference value (also referred to as a second difference value) between the voltage V(L) and the voltage V(L)′ is greater than a critical value. If at least one of the first difference value and the second difference value is greater than the critical value, the control circuit 13 may determine that the change of at least one of the voltages V(H) and V(L) is greater than the critical value. However, if both the first difference value and the second difference value are not greater than the critical value, the control circuit 13 may determine that the changes of the voltages V(H) and V(L) are not greater than the critical value.

In an exemplary embodiment, in response to a change in at least one of the voltages V(H) and V(L) being greater than a critical value, the control circuit 13 may adjust at least one of the reference voltage levels Vref(1) to Vref(n). The operation details on how to adjust the reference voltage levels Vref(1) to Vref(n) are described in the foregoing paragraphs, so description thereof is not repeated herein. However, in an exemplary embodiment, if the change of at least one of the voltages V(H) and V(L) is not greater than a critical value, the control circuit 13 may not adjust at least one of the reference voltage levels Vref(1) to Vref(n).

In an exemplary embodiment, in response to a change in at least one of the voltages V(H) and V(L) being greater than a critical value, the control circuit 13 may trigger an adjustment of at least one of the reference voltage levels Vref(1) to Vref(n). However, if the change of at least one of the voltages V(H) and V(L) is not greater than a critical value, the control circuit 13 may not trigger the adjustment of at least one of the reference voltage levels Vref(1) to Vref(n).

In an exemplary embodiment, at least one of the reference voltage levels Vref(1) to Vref(n) is adjusted only when the change of at least one of the voltage V(H) (i.e., the first critical voltage) and the voltage V(L) (i.e., the second critical voltage) is greater than a critical value, so that the number of times or frequency of adjusting the reference voltage levels Vref(1) to Vref(n) may be reduced. In this way, the occurrence of unexpected errors may be reduced, and that the operational stability of the signal receiving circuit 10 is improved.

FIG. 6 is a schematic diagram of a signal receiving circuit according to an exemplary embodiment of the disclosure With reference to FIG. 6, a signal receiving circuit 60 includes an equalizer circuit (also referred to as a first equalizer circuit) 61, a sensing circuit (also referred to as a multi-stage sensing circuit) 62, an equalizer circuit (also referred to as a second equalizer circuit) 63, a clock and data recovery (CDR) circuit 64, a detecting circuit (also referred to as an edge detecting circuit) 65, and a control circuit 66.

The equalizer circuit 61 is configured to obtain (e.g., receive) a signal (also referred to as an input signal) Sin. The equalizer circuit 61 is configured to perform compensation (also referred to as first compensation) on the signal Sin to generate the signal S1 (i.e., the first signal). For instance, the equalizer circuit 61 may include a continuous time linear equalizer (CTLE), a variable gain amplifier (VGA), and/or other circuits suitable for compensating (or optimizing) the signal S1.

The sensing circuit 62 is coupled to the equalizer circuit 61. The sensing circuit 62 may be configured to obtain (e.g., receive) the signal S1 and the reference voltage levels Vref(1) to Vref(n). Next, the sensing circuit 62 may be configured to sense the voltage relative relationship between the signal S1 and the reference voltage levels Vref(1) to Vref(n). For instance, the sensing circuit 62 may include the sensing circuit 11 of FIG. 1. The relevant operation details are described in the foregoing paragraphs, so description thereof is not repeated herein. In addition, the sensing circuit 62 may generate a signal (also referred to as a second signal) S2 according to the signal S1. A waveform of the signal S2 may be (almost) the same as a waveform of signal S1. In an exemplary embodiment, the sensing circuit 62 may directly transmit the signal S1 to the equalizer circuit 63 as the signal S2.

The equalizer circuit 63 is coupled to the sensing circuit 62. The equalizer circuit 63 is configured to obtain (i.e., receive) the signal S2. The equalizer circuit 63 is configured to compensate the signal S2 (also referred to as second compensation) to generate a signal (also referred to as a third signal) S3. For instance, the equalizer circuit 63 may include a decision feedback equalizer (DFE) and/or other circuits suitable for compensating (or optimizing) the signal S2.

It should be noted that in an exemplary embodiment, the configuration order of the equalizer circuit 61, the sensing circuit 62, and the equalizer circuit 63 and the circuits included therein may be adjusted according to practical needs, which is not limited by the disclosure. In addition, in an exemplary embodiment, the equalizer circuits 61 and 63 may also be combined into a single equalizer circuit 61 or 63, which is not limited by the disclosure.

The clock and data recovery circuit 64 is coupled to the equalizer circuit 63. The clock and data recovery circuit 64 may obtain (e.g., receive) the signal S3. The clock and data recovery circuit 64 may be configured to perform at least one of frequency tracking and phase tracking on the signal S3 to generate a signal (also referred to as a fourth signal) S4. For instance, the clock and data recovery circuit 64 may be configured to perform frequency tracking and/or phase tracking on the signal S3, so that a frequency and a phase of the signal S3 may be continuously maintained in a state of being aligned with a frequency and a phase of a reference clock signal. In an exemplary embodiment, the clock and data recovery circuit 64 may also adjust the frequency and/or phase of the reference clock signal according to the result of performing frequency tracking and/or phase tracking on the signal S3.

The detecting circuit 65 is coupled to the clock and data recovery circuit 64. The detecting circuit 65 may obtain (e.g., receive) the signal S4. The detecting circuit 65 may obtain (e.g., detect) the edge information EI of the signal S1 according to the signal S4. Then, the detecting circuit 65 may provide the edge information EI of the signal S1 to the control circuit 66. For instance, the detecting circuit 65 may include the detecting circuit 12 of FIG. 1. It should be noted that in the exemplary embodiment of FIG. 6, a waveform of signal S4 may be (almost) the same as the waveform of signal S. Therefore, the detecting circuit 65 may obtain (e.g., detect) the edge information EI of the signal S1 by analyzing the signal S4. The relevant operation details are described in the foregoing paragraphs, so description thereof is not repeated herein.

The control circuit 66 is coupled to the detecting circuit 65 and the sensing circuit 62. The control circuit 66 may obtain (e.g., receive) the edge information EI of the signal S1. The control circuit 66 may adjust at least one of the reference voltage levels Vref(1) to Vref(n) according to the edge information EI of the signal S1. For instance, the control circuit 66 may include the control circuit 13 of FIG. 1. The relevant operation details are described in the foregoing paragraphs, so description thereof is not repeated herein.

It should be noted that the layouts of the electronic circuits shown in FIG. 1 and FIG. 6 are merely examples and are not intended to limit the disclosure. In some applications not mentioned, more electronic components and/or electronic circuits may be added to the signal receiving circuit to provide additional functions. In addition, in some applications not mentioned, the circuit layout and/or component coupling relationship within the signal receiving circuit may also be appropriately changed to meet practical needs.

In an exemplary embodiment, the signal receiving circuit 10 of FIG. 1 and/or the signal receiving circuit 60 of FIG. 6 may be arranged in a memory storage device. In an exemplary embodiment, the signal receiving circuit 10 of FIG. 1 and/or the signal receiving circuit 60 of FIG. 6 may also be arranged in other types of electronic devices, and are not limited to memory storage devices.

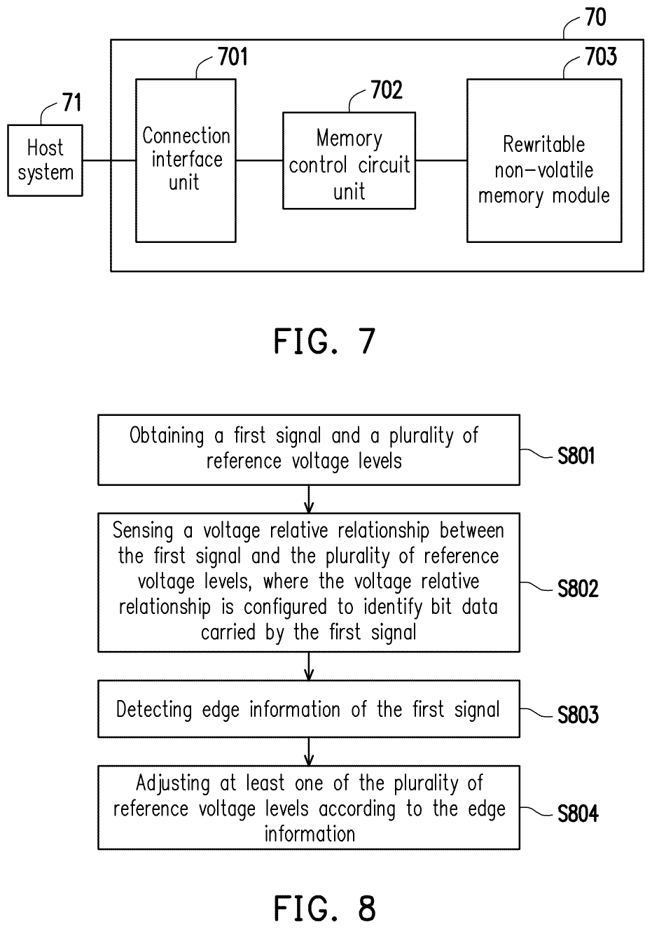

FIG. 7 is a schematic view illustrating a memory storage device according to an exemplary embodiment of the disclosure. With reference to FIG. 7, a memory storage device 70 is a memory storage device such as a solid state drive (SSD) or a flash drive, etc., which includes a rewritable non-volatile memory module 703. The memory storage device 70 may be used together with a host system 71. For instance, the host system 71 may write data into the memory storage device 70 or may read data from the memory storage device 70. For instance, the host system 71 is any system that can actually work with the memory storage device 70 to store data, such as a smart phone, a tablet computer, a laptop computer, a desktop computer, a server, an industrial computer, or a computer system installed in a specific carrier such as a vehicle, an aircraft, or a ship.

The memory storage device 70 includes a connection interface unit 701, a memory control circuit unit 702, and a rewritable non-volatile memory module 703. The connection interface unit 701 is configured to connect the memory storage device 70 to the host system 71. In an exemplary embodiment, the connection interface unit 701 is compatible with the peripheral component interconnect express (PCI Express) standard. In an exemplary embodiment, the connection interface unit 701 may also be compatible with the serial advanced technology attachment (SATA), parallel advanced technology attachment (PATA), universal serial bus (USB), or other suitable standards. The connection interface unit 701 may be packaged in a chip together with the memory control circuit unit 702, or the connection interface unit 701 may also be disposed outside a chip including the memory control circuit unit 702.

The memory control circuit unit 702 is coupled to the connection interface unit 701 and the rewritable non-volatile memory module 70. The memory control circuit unit 702 is configured to execute operations of data writing, reading, or erasing in the rewritable non-volatile memory module 703 according to a command of the host system 71. In an exemplary embodiment, the memory control circuit unit 702 includes a memory controller. For instance, this memory controller may be a flash memory controller.

The rewritable non-volatile memory module 703 is configured to store data written by the host system 71. For instance, the rewritable non-volatile memory module 703 may include a single level cell (SLC) NAND flash memory module (i.e., a flash memory module capable of storing 1 bit in one memory cell), a multi level cell (MLC) NAND flash memory module (i.e., a flash memory module capable of storing 2 bits in one memory cell), a triple level cell (TLC) NAND flash memory module (i.e., a flash memory module capable of storing 3 bits in one memory cell), a quad level cell (QLC) NAND flash memory module (i.e., a flash memory module capable of storing 4 bits in one memory cell), or any memory module having the same or similar features.

In an exemplary embodiment, the signal receiving circuit 10 of FIG. 1 and/or the signal receiving circuit 60 of FIG. 6 may be arranged in the connection interface unit 701 of FIG. 7 to receive and process signals from the host system 71. Taking FIG. 6 as an example, if the signal receiving circuit 60 is arranged in the connection interface unit 701, the signal Sin may be a signal from the host system 71 (e.g., a data signal or an arbitrary signal).

In an exemplary embodiment, the connection interface unit 701 (i.e., the signal receiving circuit 10 of FIG. 1 or the signal receiving circuit 60 of FIG. 6) may be used to establish a connection between the host system 71 and the memory storage device 70. In an exemplary embodiment, this connection may also be regarded as a connection between the connection interface unit 701 (i.e., the signal receiving circuit 10 of FIG. 1 or the signal receiving circuit 60 of FIG. 6) and the host system 71.

In an exemplary embodiment, during the establishment of the connection, the connection interface unit 701 (i.e., the signal receiving circuit 10 of FIG. 1 or the signal receiving circuit 60 of FIG. 6) may be used to perform a handshake operation with the host system 71. The handshake operation is used to exchange information related to the connection to be established between the host system 71 and the memory storage device 70, such as power information and/or clock information. After the connection is established, the connection interface unit 701 (i.e., the signal receiving circuit 10 of FIG. 1 or the signal receiving circuit 60 of FIG. 6) may receive a signal from the host system 71 or send a signal to the host system 71 through the connection.

In an exemplary embodiment, the reference voltage levels Vref(1) to Vref(n) in FIG. 1 or FIG. 6 are adjusted in real time after the connection between the memory storage device 70 and the host system 71 is established. Alternatively, from another perspective, after the connection between the memory storage device 70 and the host system 71 is established, without interrupting or reestablishing the connection, the signal receiving circuit 10 of FIG. 1 or the signal receiving circuit 60 of FIG. 6 may dynamically adjust the reference voltage levels Vref(1) to Vref(n) in FIG. 1 or FIG. 6 according to the signal received from the host system 71 through this connection.

In an exemplary embodiment, compared to the conventional method of adjusting or resetting some parameters in the connection interface unit 701 only by interrupting and reestablishing the connection between the memory storage device 70 and the host system 71, the signal receiving circuit 10 of FIG. 1 or the signal receiving circuit 60 of FIG. 6 may effectively improve the anti-interference capability (for example, errors in the signals received from the host system 71 are reduced) of the memory storage device 70 without affecting the signal transmission performance of the memory storage device 70.

FIG. 8 is a flow chart illustrating a signal generation method according to an exemplary embodiment of the disclosure. With reference to FIG. 8, in step S801, a first signal and a plurality of reference voltage levels are obtained. In step S802, a voltage relative relationship between the first signal and the plurality of reference voltage levels are sensed. In particular, this voltage relative relationship may be used to identify bit data carried by the first signal. In step S803, edge information of the first signal is detected. In step S804, at least one of the plurality of reference voltage levels is adjusted according to the edge information.

However, each step in FIG. 8 is described in detail in the foregoing paragraphs, so description thereof is not repeated herein. It should be noted that each step in FIG. 8 may be implemented as a plurality of program codes or circuits, which is not particularly limited by the disclosure. In addition, the method of FIG. 8 may be used in combination with the above-described exemplary embodiments or may be used solely, which is not particularly limited by the disclosure.

In view of the foregoing, in the signal receiving circuit, the memory storage device, and the reference voltage adjustment method provided in the exemplary embodiments of the disclosure, during the normal operation of the signal receiving circuit, the reference voltage levels used by the sensing circuit may be adjusted in real time according to the edge information of the signal. In this way, the anti-interference capability (for example, errors in the received signal are reduced) of the signal receiving device (or memory storage device) may be improved without affecting the signal transmission performance of the signal receiving device (or memory storage device).

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A signal receiving circuit, comprising:
a multi-stage sensing circuit;
an edge detecting circuit; and
a control circuit coupled to the multi-stage sensing circuit and the edge detecting circuit,
wherein the multi-stage sensing circuit is configured to obtain a first signal and a plurality of reference voltage levels,
the multi-stage sensing circuit is further configured to sense a voltage relative relationship between the first signal and the plurality of reference voltage levels, wherein the voltage relative relationship is configured to identify bit data carried by the first signal,
the edge detecting circuit is configured to detect edge information of the first signal, and
the control circuit is configured to adjust at least one of the plurality of reference voltage levels according to the edge information.

2. The signal receiving circuit according to claim 1, wherein the edge information reflects that a voltage of the first signal changes between a first critical voltage and a second critical voltage, and the operation of the control circuit adjusting the at least one of the plurality of reference voltage levels according to the edge information comprises:
adjusting the at least one of the plurality of reference voltage levels according to a change in the at least one of the first critical voltage and the second critical voltage.

3. The signal receiving circuit according to claim 2, wherein the operation of the control circuit adjusting the at least one of the plurality of reference voltage levels according to the change in the at least one of the first critical voltage and the second critical voltage comprises:
in response to the change of the at least one of the first critical voltage and the second critical voltage being greater than a critical value, adjusting the at least one of the plurality of reference voltage levels.

4. The signal receiving circuit according to claim 2, wherein the first critical voltage changes from a first voltage to a second voltage, the second critical voltage changes from a third voltage to a fourth voltage, and the operation of the control circuit adjusting the at least one of the plurality of reference voltage levels according to the change in the at least one of the first critical voltage and the second critical voltage comprises:
obtaining at least one new reference voltage level according to at least one of the second voltage and the fourth voltage; and
adjusting the at least one of the plurality of reference voltage levels according to the at least one new reference voltage level.

5. The signal receiving circuit according to claim 1, wherein the plurality of reference voltage levels comprise a first reference voltage level and a second reference voltage level, the first reference voltage level is higher than the second reference voltage level,
if the voltage relative relationship is that a voltage of the first signal is higher than the first reference voltage level, then the voltage relative relationship reflects that the bit data carried by the first signal is first bit data,
if the voltage relative relationship is that the voltage of the first signal is between the first reference voltage level and the second reference voltage level, then the voltage relative relationship reflects that the bit data carried by the first signal is second bit data, and
if the voltage relative relationship is that the voltage of the first signal is lower than the second reference voltage level, then the voltage relative relationship reflects that the bit data carried by the first signal is third bit data.

6. The signal receiving circuit according to claim 1, wherein a bit depth of the bit data is at least 2.

7. The signal receiving circuit according to claim 1, wherein the at least one of the plurality of reference voltage levels is adjusted in real time after a connection between the signal receiving circuit and a host system is established.

8. The signal receiving circuit according to claim 1, further comprising:
a first equalizer circuit coupled to the multi-stage sensing circuit;
a second equalizer circuit coupled to the multi-stage sensing circuit; and
a clock and data recovery circuit coupled to the multi-stage sensing circuit and the edge detecting circuit,
wherein the first equalizer is configured to obtain an input signal,
the first equalizer circuit is further configured to perform a first compensation on the input signal to generate the first signal,
the multi-stage sensing circuit is further configured to generate a second signal according to the first signal,
the second equalizer circuit is configured to perform a second compensation on the second signal to generate a third signal,
the clock and data recovery circuit is configured to perform at least one of frequency tracking and phase tracking on the third signal to generate a fourth signal, and
the edge detecting circuit is configured to obtain the edge information of the first signal according to the fourth signal.

9. A memory storage device, comprising:
a connection interface unit configured to be coupled to a host system;
a rewritable non-volatile memory module; and
a memory control circuit unit coupled to the connection interface unit and the rewritable non-volatile memory module,
wherein the connection interface unit comprises a signal receiving circuit configured to:
obtain a first signal and a plurality of reference voltage levels;
sense a voltage relative relationship between the first signal and the plurality of reference voltage levels, wherein the voltage relative relationship is configured to identify bit data carried by the first signal;
detect edge information of the first signal; and
adjust at least one of the plurality of reference voltage levels according to the edge information.

10. The memory storage device according to claim 9, wherein the edge information reflects that a voltage of the first signal changes between a first critical voltage and a second critical voltage, and the operation of the signal receiving circuit adjusting the at least one of the plurality of reference voltage levels according to the edge information comprises:
adjusting the at least one of the plurality of reference voltage levels according to a change in the at least one of the first critical voltage and the second critical voltage.

11. The memory storage device according to claim 10, wherein the operation of the signal receiving circuit adjusting the at least one of the plurality of reference voltage levels according to the change in the at least one of the first critical voltage and the second critical voltage comprises:
in response to the change of the at least one of the first critical voltage and the second critical voltage being greater than a critical value, adjusting the at least one of the plurality of reference voltage levels.

12. The memory storage device according to claim 10, wherein the first critical voltage changes from a first voltage to a second voltage, the second critical voltage changes from a third voltage to a fourth voltage, and the operation of the signal receiving circuit adjusting the at least one of the plurality of reference voltage levels according to the change in the at least one of the first critical voltage and the second critical voltage comprises:
obtaining at least one new reference voltage level according to at least one of the second voltage and the fourth voltage; and
adjusting the at least one of the plurality of reference voltage levels according to the at least one new reference voltage level.

13. The memory storage device according to claim 9, wherein the plurality of reference voltage levels comprise a first reference voltage level and a second reference voltage level, the first reference voltage level is higher than the second reference voltage level,
if the voltage relative relationship is that a voltage of the first signal is higher than the first reference voltage level, then the voltage relative relationship reflects that the bit data carried by the first signal is first bit data,
if the voltage relative relationship is that the voltage of the first signal is between the first reference voltage level and the second reference voltage level, then the voltage relative relationship reflects that the bit data carried by the first signal is second bit data, and
if the voltage relative relationship is that the voltage of the first signal is lower than the second reference voltage level, then the voltage relative relationship reflects that the bit data carried by the first signal is third bit data.

14. The memory storage device according to claim 9, wherein a bit depth of the bit data is at least 2.

15. The memory storage device according to claim 9, wherein the least one of the plurality of reference voltage levels is adjusted in real time after a connection between the connection interface unit and the host system is established.

16. The memory storage device according to claim 15, wherein the signal receiving circuit comprises:
a multi-stage sensing circuit;
an edge detecting circuit; and
a control circuit coupled to the multi-stage sensing circuit and the edge detecting circuit,
wherein the multi-stage sensing circuit is configured to obtain the first signal and the plurality of reference voltage levels,
the multi-stage sensing circuit is further configured to obtain the voltage relative relationship between the first signal and the plurality of reference voltage levels,
the edge detecting circuit is configured to obtain the edge information of the first signal, and
the control circuit is configured to adjust the at least one of the plurality of reference voltage levels according to the edge information.

17. The memory storage device according to claim 16, wherein the signal receiving circuit further comprises:
a first equalizer circuit coupled to the multi-stage sensing circuit;
a second equalizer circuit coupled to the multi-stage sensing circuit; and
a clock and data recovery circuit coupled to the multi-stage sensing circuit and the edge detecting circuit,
wherein the first equalizer is configured to obtain an input signal from the host system,
the first equalizer circuit is further configured to perform a first compensation on the input signal to generate the first signal,
the multi-stage sensing circuit is further configured to generate a second signal according to the first signal,
the second equalizer circuit is configured to perform a second compensation on the second signal to generate a third signal,
the clock and data recovery circuit is configured to perform at least one of frequency tracking and phase tracking on the third signal to generate a fourth signal, and
the edge detecting circuit is configured to obtain the edge information of the first signal according to the fourth signal.

18. A reference voltage adjustment method for a memory storage device, the reference voltage adjustment method comprising:
obtaining a first signal and a plurality of reference voltage levels;
sensing a voltage relative relationship between the first signal and the plurality of reference voltage levels, wherein the voltage relative relationship is configured to identify bit data carried by the first signal;
detecting edge information of the first signal; and
adjusting at least one of the plurality of reference voltage levels according to the edge information.

19. The reference voltage adjustment method according to claim 18, wherein the edge information reflects that a voltage of the first signal changes between a first critical voltage and a second critical voltage, and the step of adjusting the at least one of the plurality of reference voltage levels according to the edge information comprises:
adjusting the at least one of the plurality of reference voltage levels according to a change in the at least one of the first critical voltage and the second critical voltage.

20. The reference voltage adjustment method according to claim 19, wherein the step of adjusting the at least one of the plurality of reference voltage levels according to the change in the at least one of the first critical voltage and the second critical voltage comprises:
in response to the change of the at least one of the first critical voltage and the second critical voltage being greater than a critical value, adjusting the at least one of the plurality of reference voltage levels.

21. The reference voltage adjustment method according to claim 19, wherein the first critical voltage changes from a first voltage to a second voltage, the second critical voltage changes from a third voltage to a fourth voltage, and the operation of adjusting the at least one of the plurality of reference voltage levels according to the change in the at least one of the first critical voltage and the second critical voltage comprises:
obtaining at least one new reference voltage level according to at least one of the second voltage and the fourth voltage; and
adjusting the at least one of the plurality of reference voltage levels according to the at least one new reference voltage level.

22. The reference voltage adjustment method according to claim 18, wherein the plurality of reference voltage levels comprise a first reference voltage level and a second reference voltage level, the first reference voltage level is higher than the second reference voltage level,
if the voltage relative relationship is that a voltage of the first signal is higher than the first reference voltage level, then the voltage relative relationship reflects that the bit data carried by the first signal is first bit data,
if the voltage relative relationship is that the voltage of the first signal is between the first reference voltage level and the second reference voltage level, then the voltage relative relationship reflects that the bit data carried by the first signal is second bit data, and
if the voltage relative relationship is that the voltage of the first signal is lower than the second reference voltage level, then the voltage relative relationship reflects that the bit data carried by the first signal is third bit data.

23. The reference voltage adjustment method according to claim 18, wherein a bit depth of the bit data is at least 2.

24. The reference voltage adjustment method according to claim 18, wherein the at least one of the plurality of reference voltage levels is adjusted in real time after a connection between the memory storage device and a host system is established.

25. The reference voltage adjustment method according to claim 18, further comprising:
obtaining an input signal;
performing a first compensation on the input signal to generate the first signal;
generating a second signal according to the first signal;
performing a second compensation on the second signal to generate a third signal; and
performing at least one of frequency tracking and phase tracking on the third signal to generate a fourth signal; and
the step of obtaining the edge information of the first signal comprising:
obtaining the edge information of the first signal according to the fourth signal.
